(19) United States
(12) Patent Application Publication
(10) Pub. No.: US 2026/0211342 A1
(43) Pub. Date: Jul. 23, 2026

(54) PROJECTION EXPOSURE APPARATUS COMPRISING AN ELEMENT COMPRISING AN ELASTIC MATERIAL

(71) Applicant: Carl Zeiss SMT GmbH, Oberkochen (DE)

(72) Inventor: Julian KALLER, Koenigsbronn (DE)

(21) Appl. No.: 19/571,729

(22) Filed: Mar. 19, 2026

Related U.S. Application Data
(63) Continuation of application No. PCT/EP2024/075438, filed on Sep. 12, 2024.

(30) Foreign Application Priority Data
Sep. 20, 2023 (DE) 10 2023 209 148.8

(51) Int. Cl. G03F 7/00

(52) U.S. Cl. CPC G03F 7/70958; G03F 7/70316; G03F 7/709; G03F 7/70983; G03F 7/70991

(57) ABSTRACT

A projection exposure apparatus (1, 101) for semiconductor lithography includes an element (40, 50, 70, 90, 120, 140) with an elastic material. The element (40, 50, 70, 90, 120, 140) has a core region (48, 58, 78, 98, 128, 148) having the elastic material and a cladding region (49, 59, 79, 99, 129, 149) at least partly surrounding the core region. The cladding region (49, 59, 79, 99, 129, 149) has at least one barrier layer (81, 141, 143) and the core region (48, 58, 78, 98, 128, 148) has an elastomer and/or a thermoplastic.

### CROSS-REFERENCE TO RELATED APPLICATIONS

This is a Continuation of International Application PCT/EP2024/075438 which has an international filing date of Sep. 12, 2024, and the disclosure of which is incorporated in its entirety into the present Continuation by reference. This Continuation also claims foreign priority under 35 U.S.C. § 119(a)-(d) to and also incorporates by reference, in its entirety, German Patent Application DE 10 2023 209 148.8 filed on Sep. 20, 2023.

### FIELD

The invention relates to a projection exposure apparatus comprising an element comprising an elastic material.

### BACKGROUND

Projection exposure apparatuses for semiconductor lithography are used for producing extremely fine structures, in particular on semiconductor components or other microstructured components. The functional principle of these apparatuses is based on the production of extremely fine structures down to the nanometer range by generally reducing imaging of structures on a mask, a so-called reticle, on an element to be structured, such as, for example, a wafer, that is provided with photosensitive material. The minimum dimensions of the structures produced are directly dependent on the wavelength of the light used.

In an emission wavelength range referred to as the deep ultraviolet (DUV) range, the light sources used have wavelengths of 100 nm to 400 nm, while light sources with an emission wavelength of the order of a few nanometers, for example between 1 nm and 120 nm, in particular of the order of 13.5 nm, have increasingly being used in recent times. The described emission wavelength range is also referred to as the extreme ultraviolet (EUV) range.

In this case, the projection exposure apparatuses have to satisfy stringent and in part apparently mutually exclusive requirements. The requirements consist for example in requirements in respect of the dynamic range, the temperature regulation of individual components and the sealing of selected regions of the projection exposure apparatus with respect to one another and the sealing of lines for temperature-regulating fluids, and also the transmission of energy and signals.

In order to satisfy these requirements, elastic and/or damping materials, in particular elastomers and thermoplastics, referred to hereinafter in combination as elastomers, are usually employed in the prior art. These are permitted to have only a small variation, or if appropriate no variation at all, with regard to their physical properties under changing operating conditions and over the lifetime of the projection exposure apparatus.

In particular, the elastomers are permitted to have only a minimal outgassing rate and little permeation for undesirable substances (for example water, oxygen or nitrogen) which may lead for example to contamination or degradation of optical elements. Furthermore, a high resistance to UV radiation and reactive elements such as, for example, reactive oxygen species and/or hydrogen plasma which may be produced from a (residual) gas together with the UV radiation is required.

The elastomers currently used comprise fluoroelastomers, in particular, which are often also denoted by the abbreviations FKM and FFKM, which adequately satisfy the requirements for previous systems.

Owing to the rising requirements of new generations of projection exposure apparatuses, in particular in the field of EUV lithography, the elastomers used hitherto may no longer adequately satisfy the requirements in respect of their mechanical properties and/or the requirements in respect of the outgassing rates. This may adversely affect the imaging quality of the projection exposure apparatus immediately (mechanical properties) or over time (outgassing).

### SUMMARY

It is an object of the present invention to specify a device which eliminates or at least substantially reduces the described disadvantages of the prior art.

This object is achieved by a device having the features of the independent claims. The dependent claims relate to advantageous developments and variants of the invention.

According to one formulation, a projection exposure apparatus for semiconductor lithography according to the invention comprises an element, the element comprising an elastic material. The element is distinguished in that it comprises a core region comprising the elastic material, and a cladding region at least partly surrounding this core region, the cladding region comprising at least one barrier layer. In this case, the core region comprises an elastomer and/or a thermoplastic. These materials have very good elastic properties in conjunction with stiffness adjustable by way of the geometry and the material composition, which are advantageous when the element is used as a sealing or connecting element. The cladding region can consist of materials having a higher specific stiffness if their thickness is chosen such that the stiffness of the cladding is less than that of the core region, preferably by a factor of 2, particularly preferably by a factor of 10.

A barrier layer within the meaning of the invention is a layer configured to be impermeable to various influences. Such influences may originate for example from fluids (liquid, gaseous) and/or electromagnetic radiation such as, for example, DUV radiation (wavelength of 100 nm to 300 nm) or EUV radiation (wavelength of 1 nm to 100 nm, in particular of 13.5 nm).

The measure according to the invention makes it possible to satisfy requirements which cannot be satisfied by a single material, owing to the distribution among different regions of the element and thus also among different materials. In this case, the core region addresses predominantly physical properties such as, for example, a desired elasticity and stiffness, whereas the barrier layer in the cladding region primarily prevents the release of substances from the core region to the environment to the greatest possible extent. Conversely, the cladding region can also at least partly prevent media from outside from being able to make contact with the core region, with the result that the core region is protected against possibly harmful UV radiation to the greatest possible extent.

In this case, the element itself can serve for example to reduce or prevent the gas exchange between two different regions of a projection exposure apparatus and/or to ensure protection against electromagnetic radiation for a further component of an assembly or of the projection exposure apparatus.

The connection of the core region to the cladding region can be configured in punctiform or areal fashion. The ratio of the thickness of the core region to that of the cladding region can be very high, particularly if metals are chosen as cladding region, which have a stiffness that is orders of magnitude higher in relation to elastomers. An elastomer several millimeters thick can be coated with a gold or aluminum layer just 10 nm thick, for example. The ratio is dependent on the elasticity and stiffness of the materials used, in particular.

Furthermore, the barrier layer can comprise a material which reduces or completely prevents outgassing of a material of the core region into the environment. This has the advantage that for the selection of the material for the core region, the main emphasis may be on the physical properties and less consideration or no consideration at all need be given to the requirements in respect of the outgassing behavior of materials, these requirements often being comparatively stringent particularly in the EUV range. For the materials often used in the context of elastomers and thermoplastics, such as ethylene propylene diene (monomer) rubber (EPDM) or acrylonitrile butadiene rubber (NBR), which outgas hydrocarbons, and silicones, which outgas volatile siloxanes, thin metallic layers such as, for example, aluminum, gold or nickel or other inorganic materials such as silicon oxide, aluminum oxide and titanium oxide are suitable for the barrier layer. Furthermore, polymers are suitable which are too stiff to be a core but can be used in a thin layer as a cladding, such as polyethylene terephthalate or polyimide, for example.

In one advantageous embodiment of the invention, the barrier layer can have a transmittance of less than 1%, preferably of less than 0.1%, in the range of UV radiation, preferably for UV radiation in the range of 1 nm to 300 nm. In this case, it is advantageous if, in particular, the wavelengths that are usually used in semiconductor lithography (13.5 nm, 193 nm, 248 nm, 365 nm) are blocked. This has the advantage that any outgassing and degradation of the core region caused by the impingement of UV radiation can be reduced or completely prevented. For this purpose, the barrier layer can comprise for example aluminum or nickel or noble metals such as gold, silver, ruthenium and platinum, and also metal oxides, such as tantalum oxide (Ta2O5) or titanium oxide (TiO2), for example.

In a further embodiment, the barrier layer can comprise a material which is configured to be impermeable or to have little permeability to reactive elements. In the case of radical hydrogen, a permeability of less than 0.1% is advantageous. In the case of an environment comprising 10 ppm ozone (O3), the barrier layer should prevent degradation of the core for at least one year. Reactive elements may be embodied as oxygen species and/or as hydrogen plasma, for example, and are distinguished by a high reactivity with other elements. Particularly in EUV lithography, the reactive elements may also arise in the region of the optical elements on account of a reaction of residual gases with the EUV radiation used for imaging. For this purpose, the barrier layer can comprise for example aluminum, nickel, noble metals such as gold, silver, ruthenium and platinum, and also metal oxides.

In a further embodiment of the invention, the barrier layer can comprise a material having a permeability to water vapor of less than 10-3 g m-2 d-1. The value relates to a relative water vapor content of 85% on one side of the element and 0% water vapor content on the other side of the same element. This value can be correspondingly linearly scaled if the water vapor content on the outer side is lower than in industrial environments, which are generally kept between 40% and 60% relative humidity and at 22° C. The barrier layer can comprise for example aluminum, noble metals, such as gold, silver, ruthenium and platinum, and also metal oxides, such as silicon oxide and aluminum oxide, or metal nitrides.

In a further embodiment, the barrier layer can comprise a material having a permeability to oxygen of less than one cm³m-2*d-1*bar-1.

The value is normalized to one standard cubic centimeter (cm3) of the penetrating oxygen, i.e. to a standard pressure of 1 bar and a standard temperature of 20° C. Given one bar air pressure difference with an oxygen partial pressure of 0.2 bar at 20° C., the values should accordingly be adapted by the factor of 1/5.

The construction according to the invention comprising a cladding region and a core region thus makes it possible to split requirements made of the connecting element between the two regions, such that for example the cladding region has a low permeability to a substance for which the core region has a high permeability, or vice versa. As a result, connecting elements can be configured with properties which are not attained by the use of only one region.

Furthermore, the cladding region can comprise a plurality of layers, in particular comprising different materials as described above. This advantageously enables a combination of properties of individual layers.

In a further embodiment, the cladding region can comprise at least one layer configured as a coating. In this context, a coating is understood to mean a layer produced on a substrate (for example the core region). In this regard, a coating can be produced directly on the core region with a PVD method or CVD method or sputtering, for example. In this case, the coating itself can be configured as a single layer or as a multilayer system.

In a further exemplary embodiment, the coating can be applied to a prestretched carrier element. In this case, the carrier element can be configured both as a layer of the cladding region and as the core region itself. In the case where the carrier is configured as core region, the carrier element, through application of tensile forces, is brought from a state in which it is usually unstretched during operation into a prestretched state and is coated in the prestretched state. The layer is compressed upon transition to the original unstressed state, compressive stresses that are non-critical for the layer arising in the course of this. The stretchability of the layer configured as a coating, for example, can thereby be increased by at least a factor of two, without the layer being subject, when the connecting element is deflected from the unstretched state, to the occurrence of tensile stresses which may cause damage to the layer as a result of the layer rupturing.

Furthermore, the cladding region can be configured in wavy fashion. As a result, for example with the use of a comparatively stiff film in the cladding region it is possible to produce a certain elasticity. The wavy cladding region can be coated with a coating as explained further above. In this case, the carrier film can be prestretched and coated in the prestretched state in a manner comparable to the core region.

Furthermore, the cladding region can comprise at least one layer which is configured as a film and which comprises polyimide, PET or ethylene vinyl alcohol copolymer (EVOH), for example. This has the advantage that the film can be coated in a comparatively simple manner and serves as a carrier element for the coating.

In a further embodiment, the cladding region can be connected to the core region via an adhesion promoter. This can find application for example in the case of a multilayered cladding region comprising a film. The adhesion promoter ensures a stable connection between the core region and the cladding region, such that detachment of the connection between the core region and the cladding region can be prevented even in the event of a severe deformation of the element, as in the case of a damper, for example.

Furthermore, the cladding region can have at least one predetermined mechanical weak point. Owing to the often comparatively lower elasticity of the cladding region in comparison with the core region, it should be expected that the cladding region will tear at a number of points and may locally lose its function as a result. In the case of a cladding region for reducing the permeability, the permeability of the element overall increases as a result. If the core region is surrounded by the cladding region on two sides, the case may arise that the damaged regions in the two cladding regions by chance lie one above the other perpendicular to the extent of the element, such that an unwanted medium can pass through the element in a comparatively simple manner on account of the resultant short path.

The predetermined mechanical weak points can be configured in offset fashion particularly in the case of two opposite cladding regions, thus giving rise to a kind of labyrinth seal. The medium, such as water or oxygen, for example, thus has to migrate through the material at least regionally in the plane of extent of the element, whereby the path for the medium is increased and the permeability of the element is reduced.

The permeability of the element that is relevant to the application can thus be predicted more accurately as well.

In a further embodiment, the element can be arranged in an assembly, which in particular comprises a protective device. The protection against UV radiation can be effected for example by an additional protective device configured as a screen. This advantageously obviates the requirement for UV resistance for the element.

In particular, the protective device can at least partly comprise a region for neutralization and/or recombination and/or binding of ions and/or radicals and/or materials outgassing from the element. The region can be configured for example as a coating, but also in the form of a film. This additional protection can at least reduce the requirements for the element, or specific requirements can be completely obviated depending on the efficacy of the coating.

In a further embodiment, the assembly can be configured as an optical module.

Furthermore, the assembly can be configured as an end stop, wherein the element in this case can be configured as a damper within the end stop. As a result, it is possible to avoid high stress peaks in the event of a collision between a module and the end stop, whereby the risk of damage to the module can furthermore be minimized.

In addition, the assembly can be configured as a damping element. The damping element can be configured as a tuned mass damper, for example.

Furthermore, the assembly can be configured as a seal of a connection of two fluid-carrying components or as sheathing of lines for transmitting energy and/or signals.

### BRIEF DESCRIPTION OF THE DRAWINGS

Exemplary embodiments and variants of the invention are explained in more detail below with reference to the drawing, in which:

FIG. 1 schematically shows a meridional section of a projection exposure apparatus for EUV projection lithography,

FIG. 2 schematically shows a meridional section of a projection exposure apparatus for DUV projection lithography,

FIG. 3 shows a connecting element known from the prior art,

FIG. 4 shows a schematic illustration of the invention,

FIGS. 5A and 5B show a first embodiment of the invention,

FIGS. 6A-6C show a further embodiment of the invention,

FIGS. 7A and 7B show a further embodiment of the invention, and

FIG. 8 shows a detail of the invention.

### DETAILED DESCRIPTION

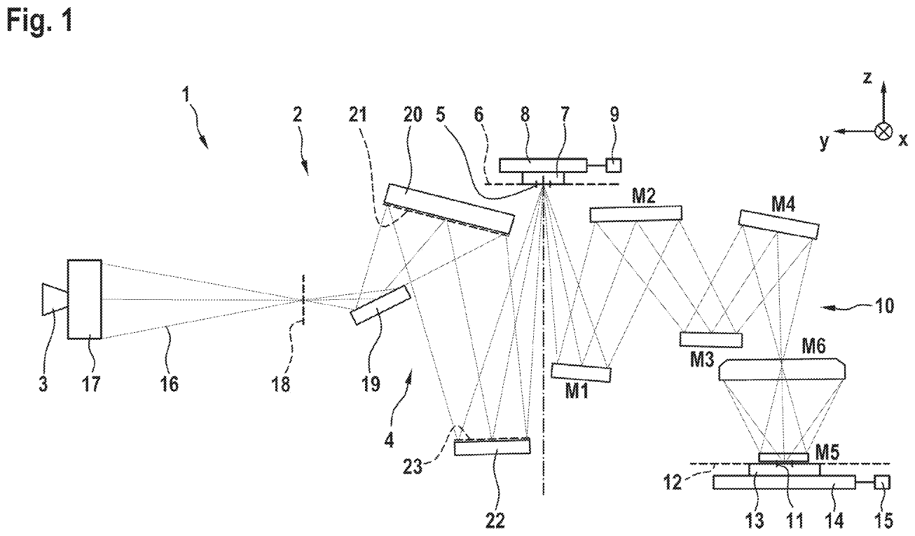

Salient constituent parts of a microlithographic projection exposure apparatus 1 are described in exemplary fashion below, initially with reference to FIG. 1. The description of the rudimentary construction of the projection exposure apparatus 1 and the constituent parts thereof is understood here to be non-limiting.

One embodiment of an illumination system 2 of the projection exposure apparatus 1 has, in addition to a radiation source 3, an illumination optical unit 4 for illuminating an object field 5 in an object plane 6. In an alternative embodiment, the light source 3 can also be provided as a module separate from the rest of the illumination system. In this case, the illumination system does not comprise the light source 3.

A reticle 7 arranged in the object field 5 is illuminated. The reticle 7 is held by a reticle holder 8. The reticle holder 8 is displaceable with a reticle displacement drive 9, in particular in a scanning direction.

For explanation purposes, a Cartesian xyz-coordinate system is depicted in FIG. 1. The x-direction runs perpendicularly to the plane of the drawing. The y-direction runs horizontally and the z-direction runs vertically. The scanning direction runs along the y-direction in FIG. 1. The 2-direction runs perpendicularly to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6. As an alternative, an angle that differs from 0° between the object plane 6 and the image plane 12 is also possible.

A structure on the reticle 7 is imaged on a light-sensitive layer of a wafer 13 arranged in the region of the image field 11 in the image plane 12. The wafer 13 is held by a wafer holder 14. The wafer holder 14 is displaceable with a wafer displacement drive 15, in particular along the y-direction. The displacement, firstly, of the reticle 7 by the reticle displacement drive 9 and, secondly, of the wafer 13 with the wafer displacement drive 15 can be implemented so as to be synchronized with one another.

The radiation source 3 is an EUV radiation source. The radiation source 3 emits, in particular, EUV radiation 16, which is also referred to below as used radiation, illumination radiation or illumination light. In particular, the used radiation has a wavelength in the range of between 5 nm and 30 nm. The radiation source 3 can be a plasma source, for example an LPP (Laser Produced Plasma) source or a GDPP (Gas Discharge Produced Plasma) source. It can also be a synchrotron-based radiation source. The radiation source 3 can be a free electron laser (FEL).

The illumination radiation 16 emanating from the radiation source 3 is focused by a collector 17. The collector 17 can be a collector with one or with a plurality of ellipsoidal and/or hyperboloidal reflection surfaces. The illumination radiation 16 can be incident on the at least one reflection surface of the collector 17 with grazing incidence (GI), i.e. at angles of incidence of greater than 45° relative to the direction of the normal to the mirror surface, or with normal incidence (NI), i.e. at angles of incidence of less than 45°. The collector 17 can be structured and/or coated, firstly to optimize its reflectivity for the used radiation and secondly to suppress extraneous light.

Downstream of the collector 17, the illumination radiation 16 propagates through an intermediate focus in an intermediate focal plane 18. The intermediate focal plane 18 can constitute a separation between a radiation source module, comprising the radiation source 3 and the collector 17, and the illumination optical unit 4.

The illumination optical unit 4 comprises a deflection mirror 19 and, disposed downstream thereof in the beam path, a first facet mirror 20. The deflection mirror 19 can be a plane deflection mirror or, alternatively, a mirror with a beam-influencing effect that goes beyond the purely deflecting effect. Alternatively or additionally, the deflection mirror 19 can be embodied as a spectral filter separating a used light wavelength of the illumination radiation 16 from extraneous light having a wavelength that deviates therefrom. If the first facet mirror 20 is arranged in a plane of the illumination optical unit 4 that is optically conjugate to the object plane 6 as a field plane, this facet mirror is also referred to as a field facet mirror. The first facet mirror 20 comprises a multiplicity of individual first facets 21, which are also referred to below as field facets. FIG. 1 illustrates only some of these facets 21 by way of example.

The first facets 21 can be embodied as macroscopic facets, in particular as rectangular facets or as facets with an arcuate edge contour or an edge contour of part of a circle. The first facets 21 can be embodied as plane facets or alternatively as convexly or concavely curved facets.

As known for example from DE 10 2008 009 600 A1, the first facets 21 themselves can also be composed in each case of a multiplicity of individual mirrors, in particular a multiplicity of micromirrors. The first facet mirror 20 can be configured in particular as a microelectromechanical system (MEMS system). For details, reference is made to DE 10 2008 009 600 A1.

Between the collector 17 and the deflection mirror 19, the illumination radiation 16 travels horizontally, i.e. along the y-direction.

In the beam path of the illumination optical unit 4, a second facet mirror 22 is disposed downstream of the first facet mirror 20. If the second facet mirror 22 is arranged in a pupil plane of the illumination optical unit 4, it is also referred to as a pupil facet mirror. The second facet mirror 22 can also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 can likewise be macroscopic facets, which can, for example, have a round, rectangular or else hexagonal boundary, or alternatively be facets composed of micromirrors. In this regard, reference is likewise made to DE 10 2008 009 600 A1.

The second facets 23 can have plane reflection surfaces or, alternatively, convexly or concavely curved reflection surfaces.

The illumination optical unit 4 consequently forms a doubly faceted system. This fundamental principle is also referred to as a fly's eye condenser (fly's eye integrator).

It can be advantageous to arrange the second facet mirror 22 not exactly in a plane that is optically conjugate to a pupil plane of the projection optical unit 10. In particular, the pupil facet mirror 22 can be arranged so as to be tilted relative to a pupil plane of the projection optical unit 10, as is described, for example, in DE 10 2017 220 586 A1.

With the aid of the second facet mirror 22, the individual first facets 21 are imaged into the object field 5. The second facet mirror 22 is the last beam-shaping mirror or else actually the last mirror for the illumination radiation 16 in the beam path upstream of the object field 5.

In a further embodiment (not illustrated) of the illumination optical unit 4, a transfer optical unit contributing in particular to the imaging of the first facets 21 into the object field 5 can be arranged in the beam path between the second facet mirror 22 and the object field 5. The transfer optical unit can have exactly one mirror or, alternatively, two or more mirrors, which are arranged in succession in the beam path of the illumination optical unit 4. The transfer optical unit can in particular comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the field facet mirror 20, and the pupil facet mirror 22.

In a further embodiment of the illumination optical unit 4, the deflection mirror 19 can also be omitted, and so the illumination optical unit 4 can then have exactly two mirrors downstream of the collector 17, specifically the first facet mirror 20 and the second facet mirror 22.

The imaging of the first facets 21 into the object plane 6 via the second facets 23 or using the second facets 23 and a transfer optical unit is routinely only approximate imaging.

The projection optical unit 10 comprises a plurality of mirrors Mi, which are consecutively numbered in accordance with their arrangement in the beam path of the projection exposure apparatus 1.

In the example illustrated in FIG. 1, the projection optical unit 10 comprises six mirrors M1 to M6. Alternatives with four, eight, ten, twelve, or any other number of mirrors Mi are likewise possible. The penultimate mirror M5 and the last mirror M6 each have a passage opening for the illumination radiation 16. The projection optical unit 10 is a doubly obscured optical unit. The projection optical unit 10 has an image-side numerical aperture which is greater than 0.5 and which can also be greater than 0.6 and, for example, can be 0.7 or 0.75.

Reflection surfaces of the mirrors Mi can be embodied as freeform surfaces without an axis of rotational symmetry. Alternatively, the reflection surfaces of the mirrors Mi can be designed as aspherical surfaces with exactly one axis of rotational symmetry of the reflection surface shape. Just like the mirrors of the illumination optical unit 4, the mirrors Mi can have highly reflective coatings for the illumination radiation 16. These coatings can be designed as multilayer coatings, in particular with alternating layers of molybdenum and silicon.

The projection optical unit 10 has a large object-image offset in the y-direction between a y-coordinate of a centre of the object field 5 and a y-coordinate of the centre of the image field 11. This object-image offset in the y-direction can be of approximately the same magnitude as a z-distance between the object plane 6 and the image plane 12.

In particular, the projection optical unit 10 can have an anamorphic configuration. In particular, it has different imaging scales βx, βy in the x-and y-directions. The two imaging scales βx, βy of the projection optical unit 10 are preferably (βx, βy)=(+/−0.25, +/−0.125). A positive imaging scale β means imaging without an image inversion. A negative sign for the imaging scale β means imaging with an image inversion.

The projection optical unit 10 consequently leads to a reduction in size with a ratio of 4:1 in the x-direction, i.e. in a direction perpendicular to the scanning direction.

The projection optical unit 10 leads to a reduction in size of 8:1 in the y-direction, i.e. in the scanning direction.

Other imaging scales are likewise possible. Imaging scales with the same signs and the same absolute values in the x-direction and y-direction, for example with absolute values of 0.125 or 0.25, are also possible.

The number of intermediate image planes in the x-direction and in the y-direction in the beam path between the object field 5 and the image field 11 can be the same or can differ depending on the embodiment of the projection optical unit 10. Examples of projection optical units with different numbers of such intermediate images in the x-and y-directions are known from US 2018/0074303 A1.

In each case, one of the pupil facets 23 is assigned to exactly one of the field facets 21 for the purpose of forming a respective illumination channel for illuminating the object field 5. This can in particular result in illumination according to the Köhler principle. The far field is decomposed into a multiplicity of object fields 5 with the aid of the field facets 21. The field facets 21 generate a plurality of images of the intermediate focus on the pupil facets 23 respectively assigned thereto.

The field facets 21 are each imaged by an assigned pupil facet 23 onto the reticle 7 in a manner overlaid on one another in order to illuminate the object field 5. The illumination of the object field 5 is in particular as homogeneous as possible. It preferably has a uniformity error of less than 2%. Field uniformity can be attained by overlaying different illumination channels.

The illumination of the entrance pupil of the projection optical unit 10 can be defined geometrically with an arrangement of the pupil facets. The intensity distribution in the entrance pupil of the projection optical unit 10 can be set by selecting the illumination channels, in particular the subset of the pupil facets which guide light. This intensity distribution is also referred to as illumination setting.

A likewise preferred pupil uniformity in the region of portions of an illumination pupil of the illumination optical unit 4 which are illuminated in a defined manner can be achieved by a redistribution of the illumination channels.

Further aspects and details of the illumination of the object field 5 and in particular of the entrance pupil of the projection optical unit 10 are described below.

The projection optical unit 10 can have a homocentric entrance pupil, in particular. The entrance pupil can be accessible. It can also be inaccessible.

The entrance pupil of the projection optical unit 10 regularly cannot be exactly illuminated using the pupil facet mirror 22. In the case of imaging of the projection optical unit 10 which telecentrically images the center of the pupil facet mirror 22 onto the wafer 13, the aperture rays often do not intersect at a single point. However, it is possible to find an area in which the distance of the aperture rays determined in pairs becomes minimal. This area represents the entrance pupil or an area in real space that is conjugate thereto. In particular, this area exhibits a finite curvature.

it may be the case that the projection optical unit 10 has different positions of the entrance pupil for the tangential beam path and for the sagittal beam path. In this case, an imaging element, in particular an optical component of the transfer optical unit, should be provided between the second facet mirror 22 and the reticle 7. With the aid of this optical element, the different positions of the tangential entrance pupil and the sagittal entrance pupil can be taken into account.

In the arrangement of the components of the illumination optical unit 4 illustrated in FIG. 1, the pupil facet mirror 22 is arranged in an area conjugate to the entrance pupil of the projection optical unit 10. The field facet mirror 20 is arranged so as to be tilted with respect to the object plane 6. The first facet mirror 20 is arranged so as to be tilted with respect to an arrangement plane defined by the deflection mirror 19.

The first facet mirror 20 is arranged so as to be tilted with respect to an arrangement plane defined by the second facet mirror 22.

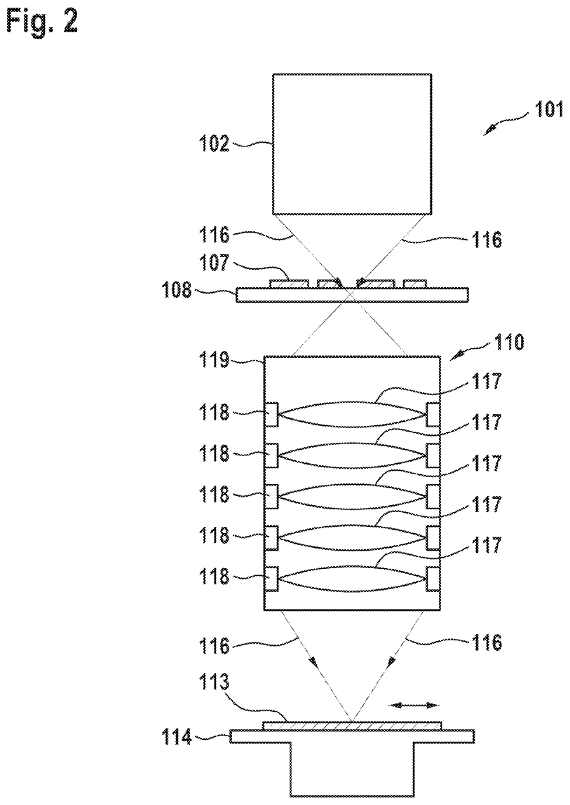

FIG. 2 schematically shows a meridional section of a further projection exposure apparatus 101 for DUV projection lithography, in which the invention can likewise be used.

The construction of the projection exposure apparatus 101 and the principle of the imaging are comparable with the construction and procedure described in FIG. 1. Identical or analogous components are denoted by a reference sign increased by 100 with respect to FIG. 1, i.e. the reference signs in FIG. 2 start at 101.

In contrast to an EUV projection exposure apparatus 1 as described in FIG. 1, refractive, diffractive and/or reflective optical elements 117, such as for example lens elements, mirrors, prisms, plane plates, and the like, can be used for imaging or for illumination in the DUV projection exposure apparatus 101 on account of the greater wavelength of the DUV radiation 116, employed as used light, in the range from 100 nm to 300 nm, in particular of 193 nm. The projection exposure apparatus 101 in this case comprises an illumination system 102, a reticle holder 108 for receiving and exactly positioning a reticle 107 provided with a structure, by which the later structures on a wafer 113 are determined, a wafer holder 114 for holding, moving, and exactly positioning the wafer 113, and a projection lens 110, with a plurality of optical elements 117, which are held by mounts 118 in a lens housing 119 of the projection lens 110.

The housing 119 is embodied in gas-tight fashion, its interior being purged with a gas under a slight excess pressure.

The illumination system 102 provides DUV radiation 116 required for the imaging of the reticle 107 on the wafer 113. A laser, a plasma source or the like can be used as the source of this radiation 116. The radiation 116 is shaped in the illumination system 102 through optical elements such that the DUV radiation 116 has the desired properties with regard to diameter, polarization, shape of the wavefront and the like when it is incident on the reticle 107.

Apart from the additional use of refractive optical elements 117, such as lens elements, prisms, terminating plates, the construction of the downstream projection optical unit 101 with the lens housing 119 does not differ in principle from the construction described in FIG. 1 and is therefore not described in further detail.

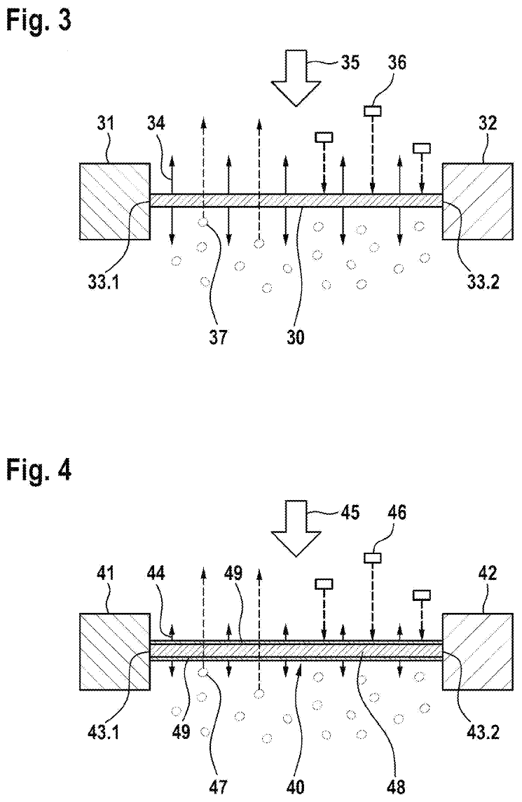

FIG. 3 shows an element known from the prior art, which is configured as a connecting element 30 and interconnects two components 31, 32, configured as module frame 31 and module receptacle 32 in the embodiment shown. The arrangement shown can serve in particular for receiving an optical element (not illustrated), such as a lens element or a mirror, for example. Alternatively, the connecting element 30 can also be directly connected to the optical element.

The connecting element 30 is formed from an elastic material such as, for example, an elastomer or a thermoplastic—combined under the term elastomer hereinafter—and is connected to the module frame 31 and the module receptacle 32 via links 33.1, 33.2.

In this case, the links 33.1, 33.2 can be configured as an adhesive connection, in which case for example an elastic adhesive such as a silane-modified polymer (SMP) or a polyurethane adhesive can find application. Alternatively, the link 33.1, 33.2 can also be configured as clamping or as any other suitable type of connection.

The connecting element 30 serves for sealing the region above the connecting element 30 and the region below the connecting element 30 with respect to one another.

In the embodiment shown in FIG. 3, the region above can correspond in particular to the region within a projection optical unit 10, 110 of a projection exposure apparatus 1, 101 as illustrated in FIG. 1 and FIG. 2. The interior of a projection optical unit 10, 110 is subject to increased cleanness requirements and is purged with high-purity gas, usually extremely dry clean air, in DUV apparatuses. In EUV apparatuses, a high vacuum is usually formed in the interior of the projection optical unit 10. The embodiment of a connecting element 30 as shown in the figure can be applied for example to a first or last optical module of a projection optical unit 110 in order to attain a gas-tight projection optical unit 110. In this case, the region below the connecting element 30 corresponds to the region outside such a projection optical unit 110, in which the requirements applicable are significantly lower than those within the projection optical unit 110. In the case of a projection optical unit 10 used in an EUV projection exposure apparatus 1, for example, two vacuum regions between the mirrors Mx can be separated from one another by the connecting element 30, as a result of which for example the flow of a hydrogen gas present in the vacuum for process engineering reasons can be directed. In this case, high vacuum prevails in both regions above and below.

The connecting element 30 thus seals the interior of the projection optical unit 10, 110 with respect to its environment, i.e. prevents with a low permeability, for example, the ingress of water vapor 37 present in the environment in a range of 10,000 ppm into the DUV projection optical unit 110 that is purged with dry air with a water vapor content of less than 100 ppm, preferably in a range of 1 to 10 ppm. The penetration of the water vapor 37 through the connecting element 30 is illustrated by a dashed arrow in FIG. 3.

Furthermore, the connecting element 30 is configured robustly to withstand the UV radiation (DUV, EUV) used for the imaging, this radiation being symbolized by the arrow 35 in FIG. 3. In addition, the connecting element 30 is also resistant to reactive elements 36, such as reactive oxygen species and/or atomic hydrogen, which may be produced by a reaction between the UV radiation 35 and at least one constituent of the dry air or a residual gas in the high vacuum in the projection optical unit 10, 110.

The elasticity and/or stiffness of the connecting element 30 influence(s) the forces and moments transmitted to the module receptacle 32 by the connection to the module frame 31. The forces and moments may cause a deformation of an optical element configured for example as a lens element (not illustrated), which may adversely affect the imaging quality of the projection exposure apparatus.

The connecting element 30 itself must not exceed a predetermined outgassing rate of outgassings, which are symbolized by arrows 34 proceeding from the surface of the connecting element 30 in FIG. 3. This requirement needs to be satisfied in combination with the properties described further above.

The increased requirements in respect of the connecting element that are arising with the advent of new generations of projection exposure apparatuses are increasingly no longer able to be sufficiently satisfied by connecting elements of the kind of the connecting element 30 shown.

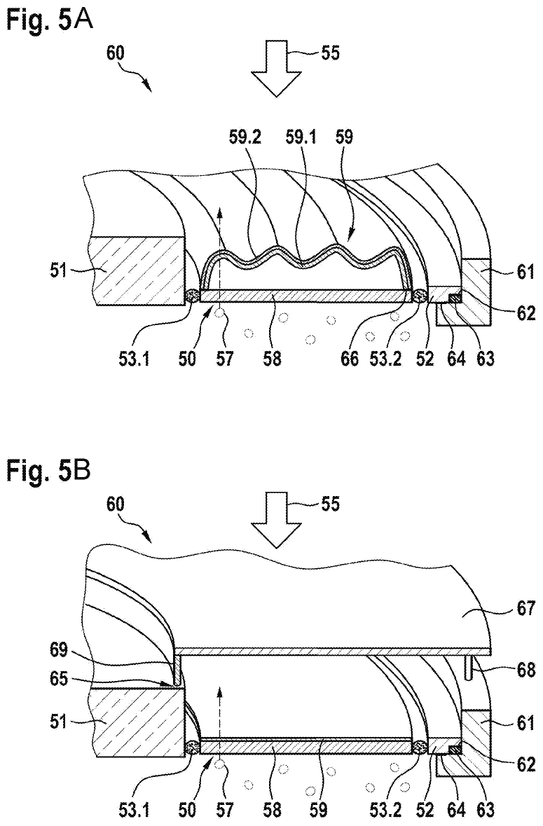

FIG. 4 shows a schematic illustration of an element according to the invention, which is configured as a connecting element 40 and, as in FIG. 3, connects a first component configured as a module frame 41 and a second component configured as a module receptacle 42, in which case, where practical, identical or comparable elements that correspond to one another are denoted by reference signs increased by 10 relative to FIG. 3. The connecting element 40 is connected to the components 41, 42 via the links 43.1, 43.2.

In contrast to the connecting element 30 comprising only one material as described in FIG. 3, the connecting element 40 according to the invention comprises a further material.

The connecting element 40 comprises a core region 48 comprising a first material and a cladding region 49 comprising the second material, the cladding region 49 surrounding the core region 48 at least at the side directed upwards and downwards in FIG. 4, i.e. partly surrounding this core region.

The core region 48 furthermore comprises an elastomer or a thermoplastic—referred to in combination as elastomer hereinafter—which fulfils in particular the mechanical properties necessary for satisfying the requirements, such as stiffness and elasticity.

The cladding region 49 comprises a material which fulfils in particular the properties necessary for satisfying the further requirements, such as protecting the environment against outgassing of the first material of the core region 48 and protecting the first material against UV radiation 45 and/or reactive elements 46 such as, for example, oxygen species and/or hydrogen plasma.

The permeability of the cladding region 49 is configured so that, firstly, outgassing from the core region 48 into the environment can be reduced or even completely prevented. In particular, outgassing from the core region 48 into the region above the connecting element 40, i.e. into the interior of the projection exposure apparatus 10, 110 (FIG. 1, FIG. 2), can be advantageously prevented with a suitably selected material for the cladding region 49. Secondly, the cladding region 49 in conjunction with the core region 48 reduces or prevents the ingress of substances from outside the projection optical unit 10, 110 into the interior thereof. In this case, the cladding region 49 and the core region 48 can thus complement one another so that for example the cladding region 49 has a low permeability to a substance for which the core region 48 has a high permeability which would not satisfy the predetermined requirements, or vice versa.

The properties of the two materials of the core region 48 and the cladding region 49 thus complement one another and can thereby advantageously satisfy jointly the predetermined requirements in respect of the connecting element 40 with a suitable selection and arrangement. In comparison with the outgassings 34 illustrated in FIG. 3, the outgassings 44 caused by the elastomer of the core region 48 are released through the cladding region 49 to the environment only to a reduced extent, which is illustrated in FIG. 4 by shorter arrows in comparison with FIG. 3.

In the embodiment shown in FIG. 4, the cladding region 49 is formed above and below the core region 48, but—depending on the requirements and installation direction of the connecting element 40—can also be formed only on one side of the core region 48, for example towards the interior of the projection optical unit 10, 110. This is the case for example if the core region 48 only needs to be protected against the UV radiation 45, but otherwise satisfies all further requirements.

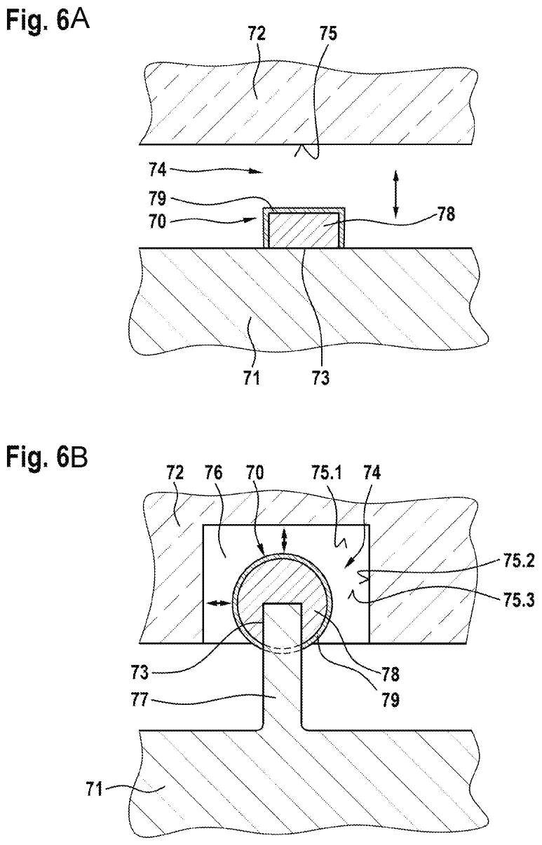

FIG. 5A shows one embodiment of a connecting element configured as a lens element seal 50 in an optical module 60. Such a module can be employed for example in one of the projection exposure apparatuses 1, 101 illustrated in FIG. 1 or FIG. 2. In the example shown, the connecting element 50 is arranged between a first component configured as a lens element 51 and a second component configured as an intermediate ring 52 and interconnects the components 51, 52 in a gas-tight manner.

The intermediate ring 52 is connected to a module receptacle 61 via a link configured as an adhesive connection 64, in which case a screw connection is also feasible. In addition, the intermediate ring 52 is sealed with respect to the module receptacle 61, i.e. with respect to the environment of the projection optical unit 10, 110 (FIG. 1, FIG. 2), by an O-ring 63 arranged in a cutout 62 formed in the intermediate ring 52.

The connecting element 50, configured as an elastomer membrane in the example shown in FIG. 5A, is connected to the lens element 51 and the intermediate ring 52 via a connection 53.1, 53.2 realized by vulcanization. Alternatively, the connection 53.1, 53.2 can also be formed by clamping or adhesive bonding.

In a further embodiment, the intermediate ring 52 can also be omitted and the connection 53.1, 53.2 of the connecting element 50 can be realized directly between the lens element 51 and the module receptacle 61.

Therefore, with regard to substances such as oxygen or water vapor, for example, penetrating through from outside a projection optical unit into the projection optical unit 10, 110, the connecting element 50 ensures a gas-tightness that also reduces or even prevents the ingress of substances by permeation. Furthermore, the forces and moments acting on the lens element 51 via the connection 53.1 are reduced to a minimum by virtue of the low stiffness of the connecting element 50.

The embodiment shown in FIG. 5A comprises a cladding region 59 configured in wavy fashion, besides the core region 58. The cladding region 59 is connected at its edges to the core region 58 via an elastic adhesive connection 66. Elastic adhesives that exhibit little outgassing, such as silane-modified polymers (SMP) or polyurethane adhesives, are feasible as adhesive. Alternatively, the cladding region 59 can overlap the joints 53.1, 53.2 and can be connected to the lens element 51 on one side and to the intermediate ring 52 on the other side.

The cladding region 59 reduces or prevents, as in the example shown, the ingress of the outgassing of the core region 58 into the interior of the projection optical unit 10, as already explained further above. The core region 58 is additionally protected against the UV radiation 55, such that the material of the core region 58 can be selected independently of any possible unwanted outgassing and its resistance to UV radiation 55. In order to improve the resistance of the cladding region 59 to the UV radiation, a first carrier element 59.1 can be coated with a coating 59.2, which can be configured in particular as a metal coating. One material preferably used is aluminum, which has good resistance to UV radiation 55 and the plasmas generated by the UV radiation 55.

The wavy configuration of the cladding region 59 firstly has the advantage that the stiffness of the cladding region 59 and hence the forces and moments transmitted to the lens element 51 are reduced. This makes it possible to use films comprising stiffer plastics, such as polyimide, PET or ethylene vinyl alcohol copolymer (EVOH), as carrier element 59.1. This has the advantage that the materials used for the films can be coated in a relatively simple manner.

Secondly, the wavy shape can contribute to the coating 59.2 being able to be applied in prestressed fashion. In this case, the cladding region that is wavy during operation is coated in a plane state, as a result of which the layer is compressed upon transition to the wavy shape, giving rise to compressive stresses that are non-critical for the layer. The stretchability of the coating 59.2 can thereby be increased by at least a factor of two, without the layer being subject, when the cladding region is deflected from its wavy shape to a plane state, to the occurrence of tensile stresses which may cause damage to the layer as a result of the layer rupturing.

In the case of an outgassing core region 58 and/or a deficient resistance to UV radiation 55 and/or the presence of reactive elements 46, the coating 59.2 is advantageously arranged on that side of the core region 58 which is directed towards the interior of the projection optical unit 10, 110. In the case where the core region 58 has an excessively high permeability to a substance that is not wanted in the interior of the projection optical unit 10, 110, the coating 59.2 can also be applied only on the outer side. Alternatively, the cladding region 59 can also be arranged on both sides of the core region 58.

As an alternative to a cladding region 59 configured in wavy fashion, the cladding region can also be configured in plane fashion. In this case, an areal adhesive bonding of the core region 58 to the cladding region 59 is also feasible.

FIG. 5B shows a further embodiment of the connecting element 50 configured as a lens element seal. The construction of the optical module 60 is predominantly identical or analogous to that illustrated in FIG. 5A, in which case, where practical, identical or analogous elements that correspond to one another are denoted according to the reference signs from FIG. 5A.

The connecting element 50 comprises a cladding region 59 configured as a coating and applied directly to the core region 58, this cladding region reducing or even completely preventing outgassing of the material of the core region 58 into the interior of the projection optical unit 10, 110. Furthermore, the permeation of oxygen and water vapor 57 into the interior of the projection optical unit 10, 110 is also avoided.

In the embodiment shown, the protection against the UV radiation 55 is ensured by a protective device configured as a shield 67. This protective device is connected to the module frame 61 via mountings 68 and comprises a lateral shield 69 in the region of the lens element 51, a gap 65 of a few mm, preferably of a few tenths of a mm, remaining between the lateral shield 69 and the lens element 51, such that the UV radiation 55 is prevented from penetrating into the region of the connecting element 50. The construction of the connecting element 50 made from at least two materials, the properties of the materials advantageously complementing one another, makes possible, by assigning the requirements to the core region 58 and the cladding region 59 and through the use of additional shields 67, 69, an advantageous flexibility for satisfying a wide variety of requirements.

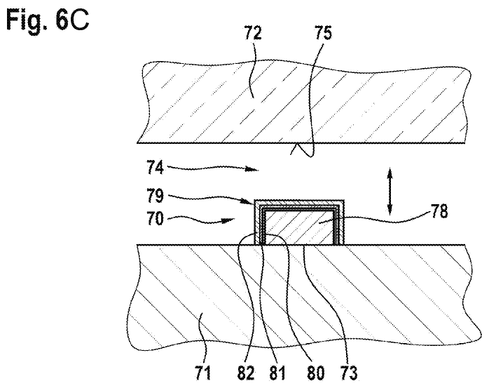

FIG. 6A shows a first embodiment of a component according to the invention configured as a damper 70 of a one-dimensional end stop 74. The damper 70 is connected to a first component configured as a module receptacle 71 via a link configured as an adhesive connection 73.

Besides the damper 70, the end stop 74 comprises a corresponding stop surface 75 arranged on a second component configured as a mirror 72.

The end stop 74 is configured so that, in the event of a possible collision between the mirror 72 and the module receptacle 71 as a result of a relative movement, represented by a double-headed arrow in FIG. 6A, damage to the components 71, 72, in particular the mirror 72, is avoided. The collision may be caused for example by an acceleration or deceleration of the projection optical unit 10, 110 that suddenly occurs during transport, in which case the mirror stops on account of its inertia in comparison with the projection optical unit 10, 110 and a relative movement occurs which may cause the collision. During the collision, the damper 70 comprising a core region 78 comprising an elastomer is deformed at the stop surface 75 and thereby absorbs the kinetic energy and dissipates this energy into heat, whereby damping is brought about. A cladding region 79 of the damper 70, as already explained further above, performs the function of minimizing or even completely preventing outgassing of the elastomer into the region of the mirror 72. Besides the single coating illustrated in the example in the figure, the construction of the cladding region 79 can also be configured as a multilayer system or a combination of a film with a coating or a combination of the multilayer system with a film with a coating. In this case, the coating can also be configured as a multilayer system.

FIG. 6B shows a further embodiment of a first component configured as a damper 70 of a three-dimensional end stop 74. The functioning of the end stop 74 corresponds to that of the end stop 74 in FIG. 6A, which is why the allocation of new reference signs has been dispensed with. In contrast to the embodiment shown in FIG. 6A, the end stop 74 comprises three stop surfaces 75.1, 75.2, 75.3 for the three spatial directions. The damper 70 is configured as a sphere connected on an arm 77 of the module frame 71 via a link 73 configured as an adhesive connection. The possible relative movements of the module frame 71 with respect to the mirror 72 are in turn represented as double-headed arrows in FIG. 6B, a relative movement perpendicularly to the plane of the drawing likewise being possible.

FIG. 6C shows a further embodiment of a first component configured as a damper 70 of a one-dimensional end stop 74, in which case, where practical, identical or analogous elements that correspond to one another are denoted by the same reference signs.

The embodiment comprises a cladding region 79 with a thin film 82 configured as carrier element with a thickness of less than 100 micrometers. The film 82 has a coating 81 comprising a material having little gas permeability, in particular a metal, on the inner side directed towards the core region 78. One suitable metal is aluminum, for example, since it can easily be applied in thin layers, in particular in a range of less than one micrometer, on plastics used for films, such as, for example, polyimide, PET or ethylene vinyl alcohol copolymer (EVOH), and does not react with the reactive elements occurring in EUV projection exposure apparatuses 1, in particular. Alternatively, noble metals can also find application as the coating 81.

The film 82 is connected to the core region 78 via an adhesive 80, but can alternatively also be directly vulcanized onto the core region 78 with the aid of an adhesion promoter or can be connected to the core region through clamping.

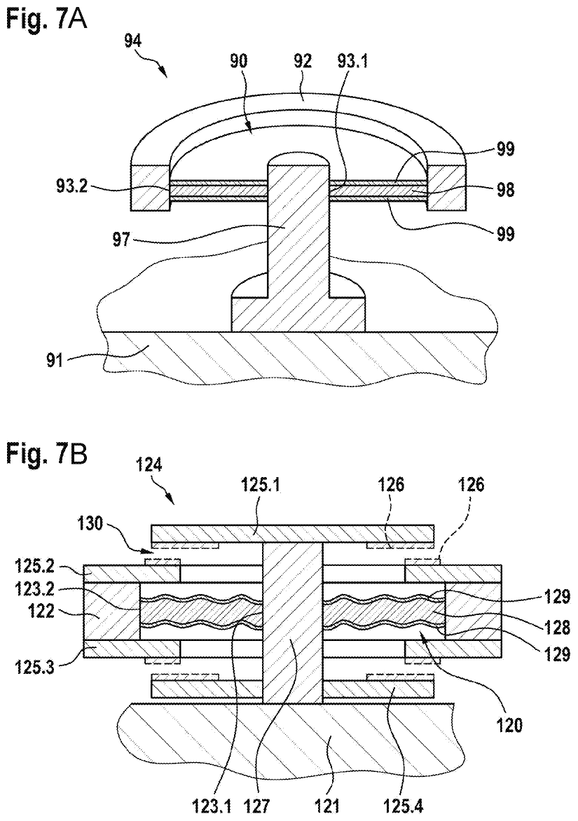

FIG. 7A shows one embodiment of an element configured as a damping membrane 90 of a tuned mass damper, which is arranged between a first component configured as a module receptacle 91 and a second component configured as a ring 92. In this case, the damping membrane 90 is connected to the two components 91, 92 via links 93.1, 93.2, the damping membrane 90 being connected to the module receptacle 91 via an arm 97 of the module receptacle 91.

The tuned mass damper 94 serves to damp vibrations of the module frame 91. In this case, the mass of the ring 92 is configured so that the natural frequency of the mass damper 94 at least almost corresponds to a natural frequency of the module frame 91, whereby the natural frequency is damped. The damping is brought about by a relative movement of the ring 92 with respect to the module frame 91 and the deformation of the damping membrane 90 that is caused as a result. The deformation results in heating of the damping membrane 90, whereby the kinetic energy of the ring 92 is dissipated. The exemplary embodiment shown can damp movements in at least one spatial direction in the plane spanned by the damping membrane 90.

According to the invention, the damping membrane 90 comprises a core region 98 comprising a first material comprising an elastomer, and a cladding region 99 comprising a second material. In the example in FIG. 7A, the cladding region 99 is formed on both sides of the core region 98 and protects the elastomer of the core region 98 against UV or EUV radiation and reactive elements, as already explained further above. In this case, the cladding region 99 is configured such that the stiffness of the damping membrane 90, this stiffness being very well defined for damping over a frequency range, is not influenced, or is influenced only in an acceptable range, by the cladding region. The cladding region 99 additionally protects that region around the mass damper 94 which is arranged in the region of the optical elements against outgassings emerging from the elastomer.

FIG. 7B shows a further embodiment of an element configured as a damping membrane 120, which connects a first component configured as a module frame 121 to a second component configured as a ring 122. The damping membrane 120 is in turn connected to an arm 127 of the module frame 121 via a link 123.1. The ring 122 is connected to the damping membrane 120 via a second link 123.2 by vulcanization.

The damping membrane 120 is configured in wavy fashion. As explained further above, this has the effect that the cladding region 129 configured as a metal layer, in particular as an aluminum or gold layer, is damaged less easily by a deformation of the damping membrane 120. The metal layer 129 is preferably configured with a thickness of less than one micrometer.

The optional additional protection against EUV radiation or UV radiation and/or reactive elements is realized by a protective device configured as screens 125.1, 125.2, 125.3, 125.4, the screens being arranged on the ring 122 and on the arm 127. The screens 125.1, 125.2, 125.3, 125.4 are arranged with respect to one another such that a minimum gap 130 is formed between the screens 125.1, 125.2, 125.3, 125.4, without the screens touching one another.

Optionally, the screens 125.1, 125.2, 125.3, 125.4 can be coated with a coating 126 comprising a material which enables good neutralization or recombination of ions or radicals, for example a metal, in particular a semi-noble metal or noble metal, such as, for example, copper, silver, palladium, platinum, gold, ruthenium, rhodium.

Alternatively or additionally, the coating 126 can comprise a material that binds harmful gases which outgas from the elastomer or arise as a result of reaction with reactive elements. This can be for example a material such as nickel or a noble metal, such as, for example, platinum, rhodium or ruthenium.

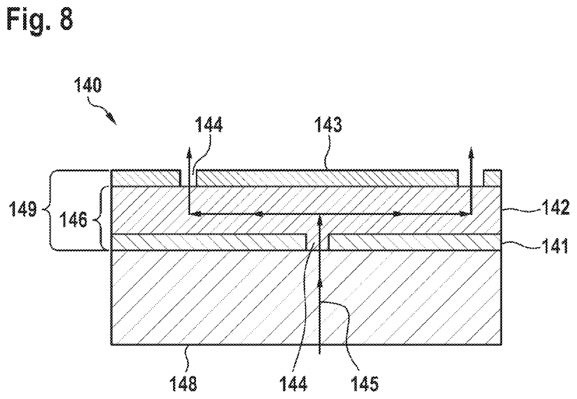

FIG. 8 shows a schematic illustration of a construction of an element 140, where the element 140 can constitute a lens element seal, a damper of an end stop or a vibration membrane. The construction comprises a core region 148 and a cladding region 149, the cladding region 149 in the example shown comprising a coating 141, a polymer 142 and a further coating 143. The illustration serves to describe the mode of action of a cladding region 149 configured as such, in particular in the case of one or both coatings 141, 143 having small defects 144, such as holes or cracks, as a result of the production process or a deformation of the element 140.

Despite these defects 144, a substance for permeation through the element 140 from the side facing the core region 148 to the side facing the cladding region 149, within the polymer 142, has to migrate at least regionally parallel to the extent of the polymer 142. This effect has a similar action to a labyrinth seal and advantageously reduces the permeability of the element 140, as represented by the arrow 145 in FIG. 8, even in the case of damage to the coatings with low permeability.

The coatings 141, 143 can have weak points predetermined during production, which causes frequently unavoidable damage to the coatings 141, 143 at predetermined points. As a result, the effect explained above can be controlled in a targeted manner and a better predictability of the permeability of the element 140 can be attained.

Furthermore, the polymer 142 can be configured to have a low permeability to a substance, whereby the effect is also intensified. The coatings 141, 143 protect the environment against possible outgassings of the polymer 142 and the polymer 142 against UV radiation and plasmas.

### List of Reference Signs

1 Projection exposure apparatus
2 Illumination system
3 Radiation source
4 Illumination optical unit
5 Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 EUV radiation
17 Collector
18 Intermediate focal plane
19 Deflection mirror
20 Facet mirror
21 Facets
22 Facet mirror
23 Facets
30 Connecting element
31 First component
32 Second component
33.1, 33.2 Link
34 Outgassing
35 UV radiation
36 Reactive elements
37 Water vapor
40 Connecting element
41 First component
42 Second component
43.1, 43.2 Link
44 Outgassing
45 UV radiation
46 Reactive elements
47 Water vapor
48 Core region
49 Cladding region
50 Lens element seal
51 Optical element
52 Intermediate ring
53.1, 53.2 Link
55 UV radiation
57 Water vapor
58 Core region
59, 59.1, 59.2 Cladding region
60 Optical module
61 Module receptacle
62 Cutout
63.1, 63.2 Link
64 Adhesive connection
65 Gap
66 Adhesive connection
67 Shield
68 Mounting of shield
69 Shield lateral
70 End stop
71 Module frame
72 Mirror
73 Link
74 End stop
75 Contact surfaces of end stop x-, y-, z-directions
76 Cutout
77 Arm of end stop
78 Core region
79 Cladding region
80 Film
81 Coating
82 Adhesive
90 Connecting element
91 First component
92 Second component
93.1, 93.2 Link
94 Mass damper
97 Arm of mass damper
98 Core region
99 Cladding region
101 Projection exposure apparatus
102 Illumination system
107 Reticle
108 Reticle holder
110 Projection optical unit
113 Wafer
114 Wafer holder
116 DUV radiation
117 Optical element
118 Mounts
119 Lens housing
120 Element
121 First component
122 Second component
123.1, 123.2 Link
124 Mass damper
125 Screens
126 Coating
127 Arm of mass damper
128 Core region
129 Cladding region
130 Gap
140 Element
141 Coating
142 Polymer
143 Coating
144 Defects in coating
145 Path of the substance during permeation
146 Layer stack
148 Core region
149 Cladding region
M1-M6 Mirrors

What is claimed is:

1. A projection exposure apparatus for semiconductor lithography comprising:
a first component and a second component, and
an element arranged in an assembly configured as an end stop between the components and comprising a core region comprising an elastic material and a cladding region at least partly surrounding the core region, wherein:
the cladding region comprises at least one barrier layer,
the core region comprises an elastomer and/or a thermoplastic, and
the core region and the cladding region are interconnected arealy.

2. The projection exposure apparatus according to claim 1, wherein the barrier layer comprises a material which reduces or prevents outgassing of a material of the core region into a surrounding environment.

3. The projection exposure apparatus according to claim 1, wherein the barrier layer has a transmittance of less than 1% in the ultraviolet (UV) or extreme ultraviolet (EUV) wavelength range.

4. The projection exposure apparatus according to claim 1, wherein the barrier layer comprises a material which is configured to be at least essentially impermeable to reactive elements.

5. The projection exposure apparatus according to claim 1, wherein the barrier layer comprises a material having a permeability to water vapor of less than 10⁻³ g m⁻² d⁻¹.

6. The projection exposure apparatus according to claim 1, wherein the barrier layer comprises a material having a permeability to oxygen of less than one cm³ m⁻² d⁻¹ bar⁻¹.

7. The projection exposure apparatus according to claim 1, wherein the cladding region comprises a plurality of layers.

8. The projection exposure apparatus according to claim 7, wherein the plurality of layers comprise mutually differing materials.

9. The projection exposure apparatus according to claim 1, wherein the cladding region comprises at least one layer configured as a coating.

10. The projection exposure apparatus according to claim 9, wherein the coating is applied on a prestretched carrier element.

11. The projection exposure apparatus according to claim 1, wherein the cladding region has a wavy configuration.

12. The projection exposure apparatus according to claim 1, wherein the cladding region comprises at least one layer configured as a film.

13. The projection exposure apparatus according to claim 1, wherein the cladding region is connected to the core region via an adhesion promoter.

14. The projection exposure apparatus according to claim 1, wherein the cladding region has at least one predetermined mechanical weak point.

15. The projection exposure apparatus according to claim 1, wherein the assembly comprises a protective device.

16. The projection exposure apparatus according to claim 15, wherein the protective device at least partly comprises a region for neutralization and/or recombination and/or binding of ions and/or radicals and/or materials outgassing from the element.

17. The projection exposure apparatus according to claim 1, wherein the assembly further comprises an optical module.

18. The projection exposure apparatus according to claim 1, wherein the assembly is configured further as a damping element.

19. The projection exposure apparatus according to claim 1, wherein the assembly is configured further as a seal of a connection of two fluid-carrying components and/or as sheathing of lines for transmitting energy and/or signals.
